(19) United States
(12) Patent Application Publication
(10) Pub. No.: US 2026/0068250 A1
(43) Pub. Date: Mar. 5, 2026

(54) SOURCE/DRAIN SHAPING FOR RESISTANCE REDUCTION

(71) Applicant: Taiwan Semiconductor Manufactruring Co., Ltd., Hsinchu (TW)

(72) Inventors: Hung-Tai Chang, Hsinchu (TW); Chih-Chiang Chang, Zhubei City (TW); Ming-Hua Yu, Hsinchu (TW)

(21) Appl. No.: 19/001,733

(22) Filed: Dec. 26, 2024

Related U.S. Application Data
(60) Provisional application No. 63/690,106, filed on Sep. 3, 2024.

(51) Int. Cl. H10D 62/13; H10D 30/00; H10D 30/01; H10D 62/00

(52) U.S. Cl. CPC H10D 62/151; H10D 30/0191; H10D 30/502; H10D 62/021

(57) ABSTRACT

A method includes forming a plurality of semiconductor nanostructures, wherein upper ones of the plurality of semiconductor nanostructures overlap respective lower ones of the plurality of semiconductor nanostructures. A plurality of semiconductor layers are formed, each from one of the plurality of semiconductor nanostructures. The plurality of semiconductor layers are shaped through an etching process. A first semiconductor layer of the plurality of semiconductor layers is etched more than a second semiconductor layer of the plurality of semiconductor layers, wherein the first semiconductor layer is higher than the second semiconductor layer. After the plurality of semiconductor layers are shaped, an additional semiconductor layer is formed to electrically connect to the plurality of semiconductor layers.

### PRIORITY CLAIM AND CROSS-REFERENCE

This application claims the benefit of the following provisionally filed U.S. Patent application: Application No. 63/690,106, filed on Sep. 3, 2024, and entitled “SOURCE/DRAIN P-EPI SHAPING FOR RESISTANCE REDUCTION;” which application is hereby incorporated herein by reference.

### BACKGROUND

Technological advances in Integrated Circuit (IC) materials and design have produced generations of ICs where each generation has smaller and more complex circuits than the previous generations. In the course of IC evolution, functional density (for example, the number of interconnected devices per chip area) has generally increased while geometry sizes have decreased. This scaling down process generally provides benefits by increasing production efficiency and lowering associated costs.

Such scaling down has also increased the complexity of processing and manufacturing ICs, and for these advances to be realized, similar developments in IC processing and manufacturing are needed. For example, Gate-All-Around (GAA) Transistors have been introduced to replace planar transistors. The structures of the GAA transistors and methods of fabricating the GAA transistors are being developed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4, 5A, 5B, 6A, 6B, 7A, 7B, 8A, 8B, 9A, 9B, 10A, 10B, 11A, 11B, 12A, 12B, 13A, 13B, 14A, 14B, and 15-24 illustrate the views of intermediate stages in the formation of a Gate All-Around (GAA) transistor in accordance with some embodiments.

FIGS. 25-27 illustrate the views of intermediate stages in the formation of a source/drain region in accordance with alternative embodiments.

FIGS. 28-30 illustrate the views of intermediate stages in the formation of a source/drain region in accordance with alternative embodiments.

FIG. 31 illustrates a process flow for forming a GAA transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Gate All-Around (GAA) transistor and the formation methods are provided. In accordance with some embodiments, the formation of the source/drain regions of the GAA transistor includes the formation of a plurality of layers. A layer of the source/drain region having a relatively lower dopant concentration is etched back, so that the upper portions of the layer have smaller sizes than respective lower portions. By reducing the sizes of the upper portions of the lower-dopant-concentration layer, more spaces are available for the formation of an overlying higher-dopant-concentration layer. The source/drain contact plug thus may land on the higher-dopant-concertation layer entirely, and may be spaced apart from the lower-dopant-concertation layer with an enlarged process window. The contact resistance between the source/drain contact plug and the source/drain region is thus reliably reduced.

Although GAA transistors are used as an example to discuss the concept of the present disclosure, the embodiments may be applied on other types of transistors including and not limited to Complementary Field-Effect Transistors (CFETs) and the like. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

In addition, although a p-type transistor may be discussed as an example in some parts of the discussion, the concept of the present application is readily available for the formation of n-type transistors, with the conductivity types of the corresponding features inversed than in the p-type transistor.

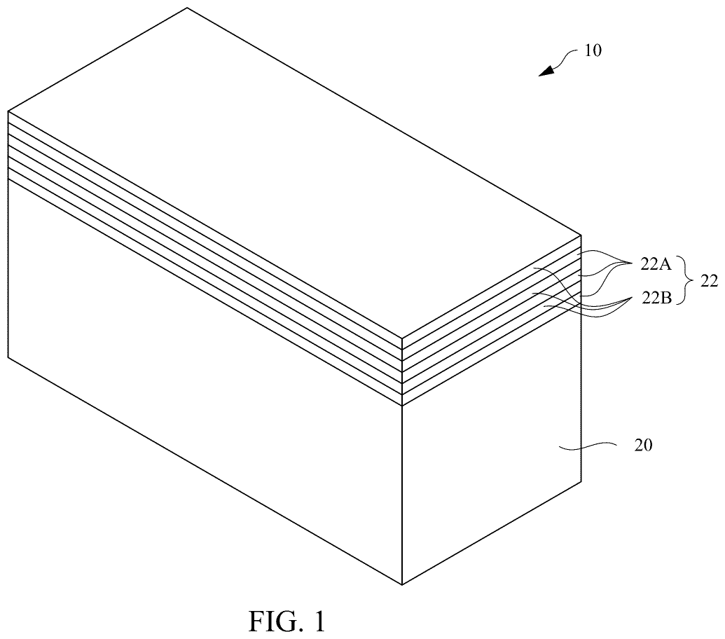

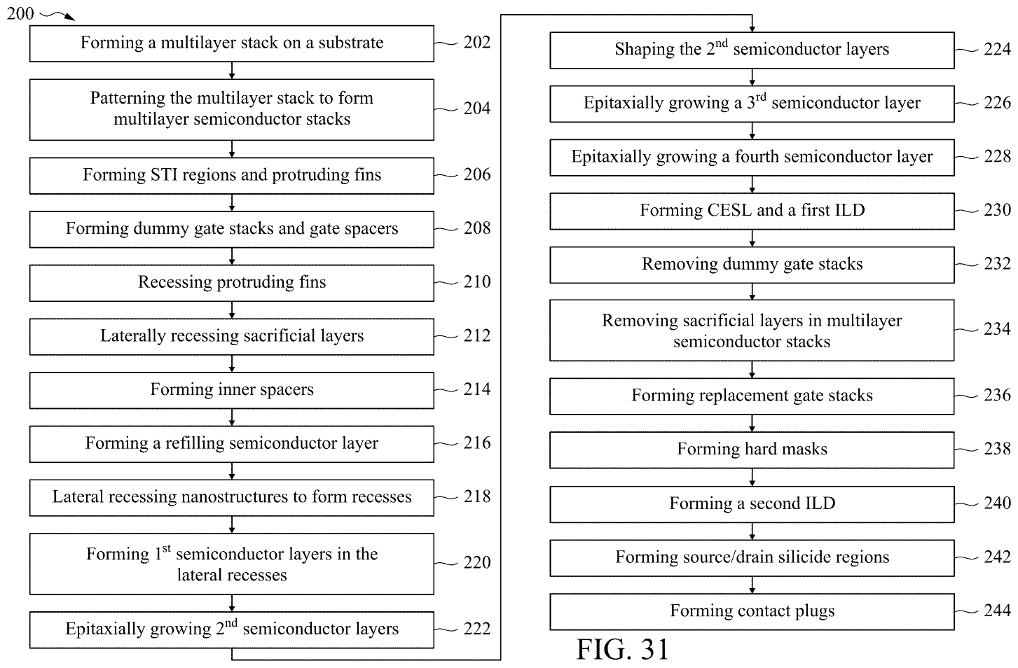

FIGS. 1-4, 5A, 5B, 6A, 6B, 7A, 7B, 8A, 8B, 9A, 9B, 10A, 10B, 11A, 11B, 12A, 12B, 13A, 13B, 14A, 14B, and 15-24 illustrate the cross-sectional views of intermediate stages in the formation of a GAA transistor in accordance with some embodiments of the present disclosure. The corresponding processes are also reflected schematically in the process flow shown in FIG. 31.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor substrate.

In accordance with some embodiments, multilayer stack 22 is formed through a series of deposition processes for depositing alternating materials. The respective process is illustrated as process 202 in the process flow 200 shown in FIG. 31. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAIAs, InGaAs, GaSbP, GaAsSb, or the like. In accordance with some embodiments, the deposition of first layers 22A (for example, SiGe) is through epitaxial growth, and the corresponding deposition method may include Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the second layer 22A has thickness in the range between about 4 nm and 7 nm, while the second layer 22B has thickness in the range between about 8 nm and 12 nm, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there may be some pad oxide layer(s) and hard mask layer(s) (not shown) formed over multilayer stack 22. These layers are patterned, and are used for the subsequent patterning of multilayer stack 22.

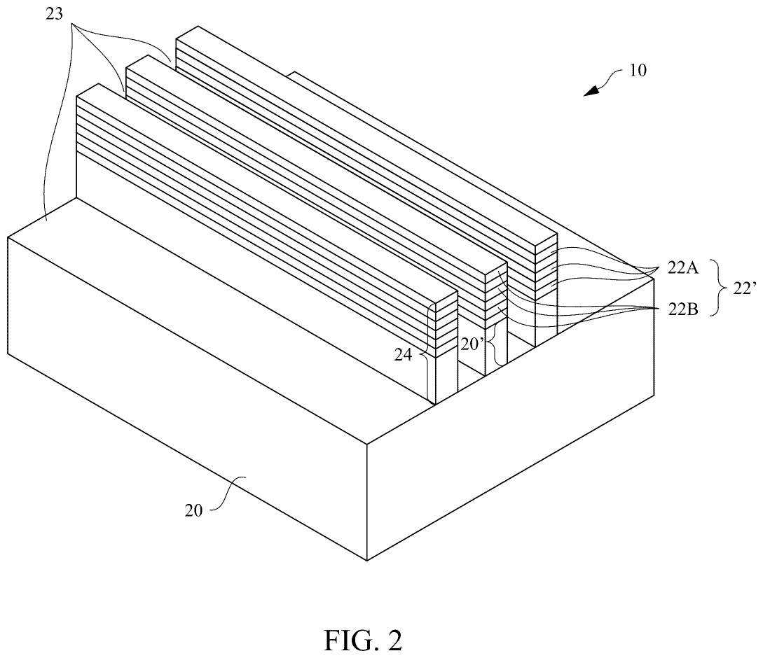

Referring to FIG. 2, multilayer stack 22 and a portion of the underlying substrate 20 are patterned in an etching process(es), so that trenches 23 are formed. The respective process is illustrated as process 204 in the process flow 200 shown in FIG. 31. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

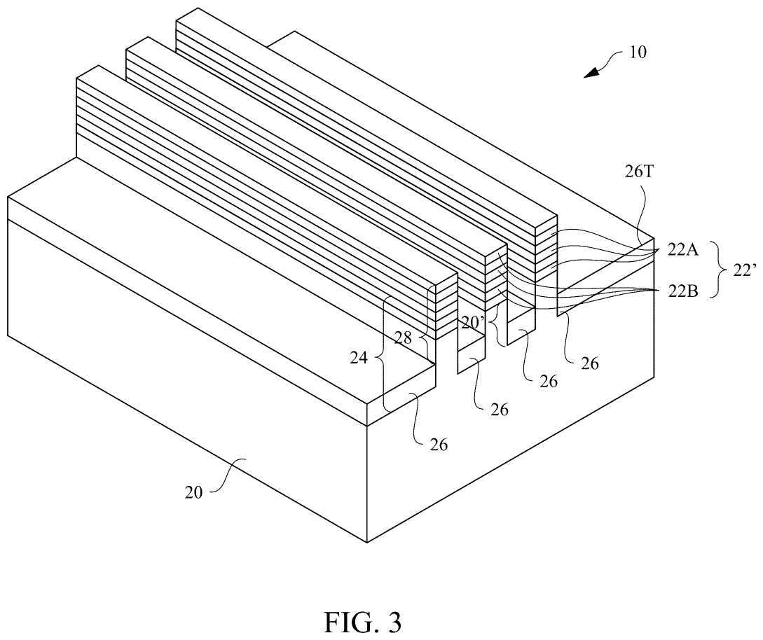

FIG. 3 illustrates the formation of isolation regions 26, which are also referred to as Shallow Trench Isolation (STI) regions throughout the description. The respective process is illustrated as process 206 in the process flow 200 shown in FIG. 31. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like.

STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

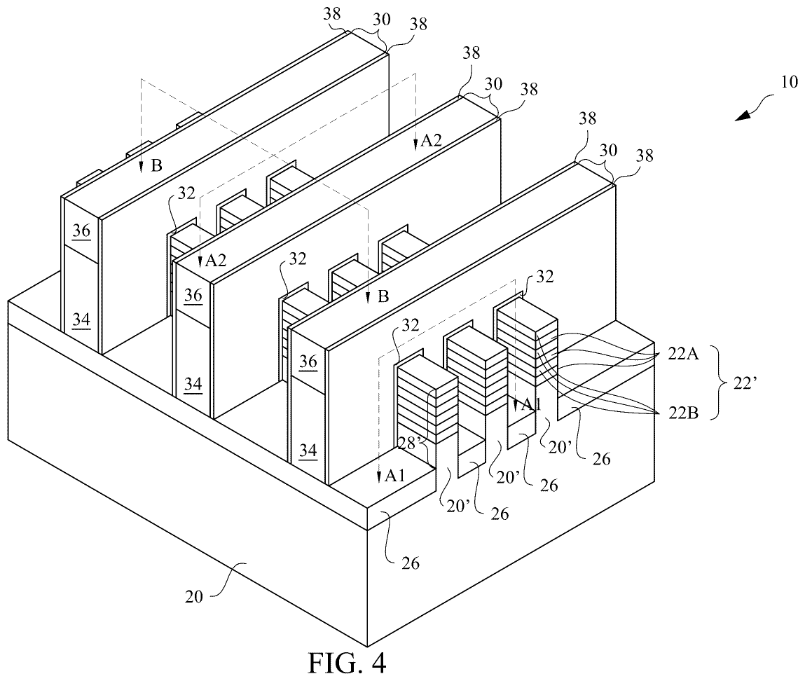

Referring to FIG. 4, dummy gate stacks 30 and gate spacers 38 are formed on the top surfaces and the sidewalls of (protruding) fins 28. The respective process is illustrated as process 208 in the process flow 200 shown in FIG. 31. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon carbide (SiC), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

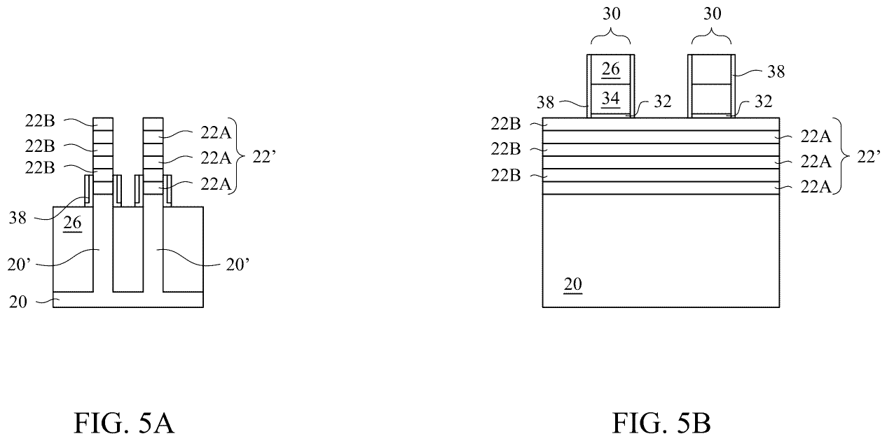

FIGS. 5A and 5B illustrate the cross-sectional views of the structure shown in FIG. 4. FIG. 5A illustrates the reference cross-section A1-A1 in FIG. 4, which cross-section cuts through the portions of protruding fins 28 not covered by dummy gate stacks 30 and gate spacers 38, and is perpendicular to the gate-length direction. FIG. 5B illustrates the reference cross-section B-B in FIG. 4, which reference cross-section is parallel to the lengthwise directions of protruding fins 28.

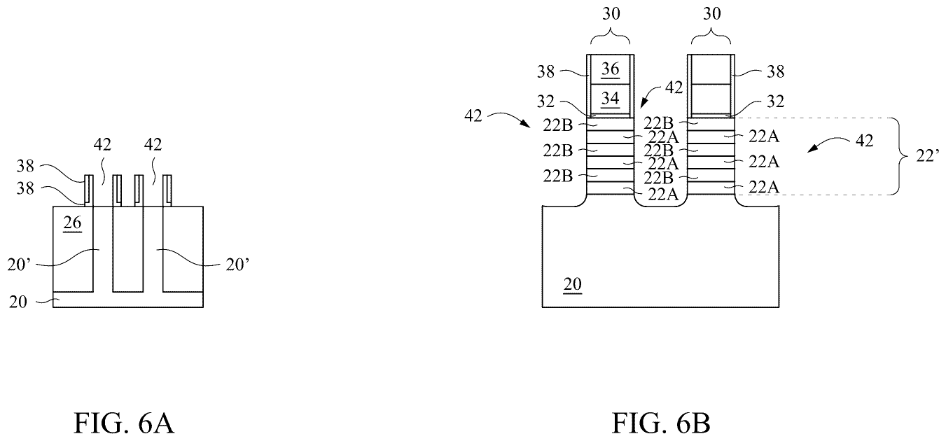

Referring to FIGS. 6A and 6B, the portions of protruding fins 28 (FIG. 4) that are not directly underlying dummy gate stacks 30 and gate spacers 38 are recessed through an etching process to form recesses 42. The respective process is illustrated as process 210 in the process flow 200 shown in FIG. 31. For example, a dry etch process may be performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying substrate strips 20′. The bottoms of recesses 42 are at least level with, or may be lower than (as shown in FIG. 6B), the bottoms of multilayer semiconductor stacks 22′. The etching may be anisotropic, so that the sidewalls of multilayer semiconductor stacks 22′ facing recesses 42 are vertical and straight, as shown in FIG. 6B.

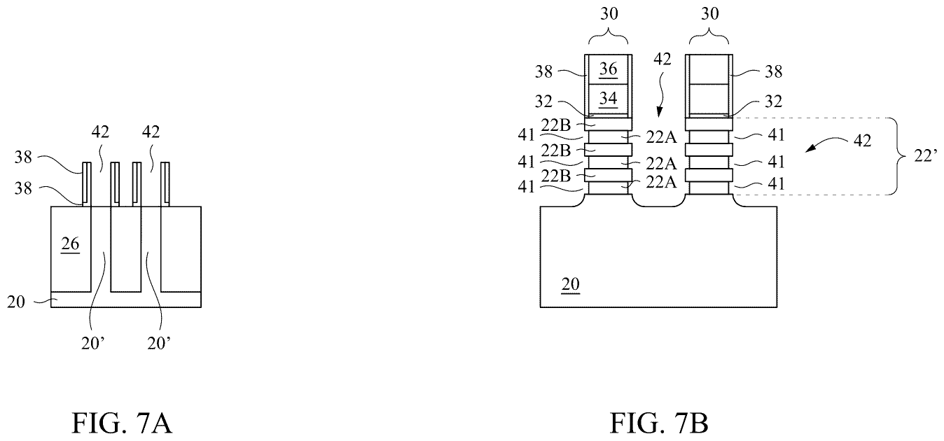

Referring to FIGS. 7A and 7B, sacrificial semiconductor layers 22A are laterally recessed to form lateral recesses 41, which are recessed from the edges of the respective overlying and underlying nanostructures 22B. The respective process is illustrated as process 212 in the process flow 200 shown in FIG. 31.

The lateral recessing of sacrificial semiconductor layers 22A may be achieved through a wet etching process using an etchant that is more selective to the material (for example, silicon germanium (SiGe)) of sacrificial semiconductor layers 22A than the material (for example, silicon (Si)) of the nanostructures 22B and substrate 20. For example, in an embodiment in which sacrificial semiconductor layers 22A are formed of silicon germanium and the nanostructures 22B are formed of silicon, the wet etching process may be performed using an etchant such as hydrochloric acid (HCl). The wet etching process may be performed using a dip process, a spray process, a spin-on process, or the like.

In accordance with alternative embodiments, the lateral recessing of sacrificial semiconductor layers 22A is performed through an isotropic dry etching process or a combination of a dry etching process and a wet etching process.

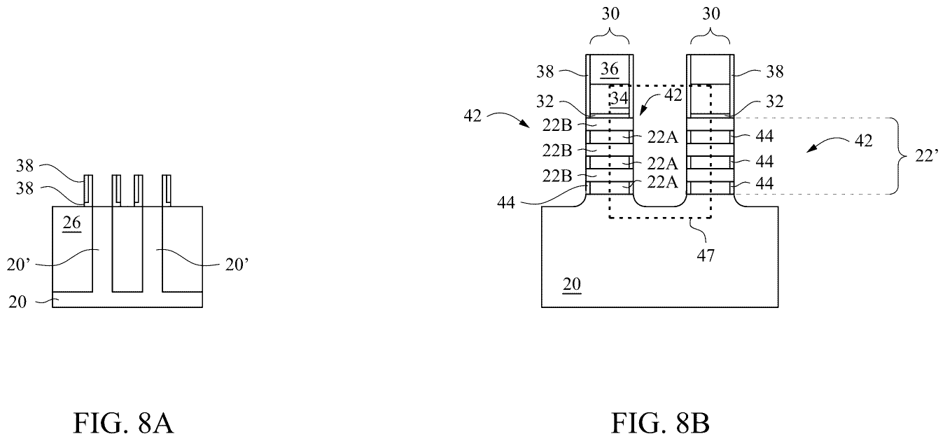

Referring to FIGS. 8A and 8B, inner spacers 44 are formed. The respective process is illustrated as process 214 in the process flow 200 shown in FIG. 31. In accordance with some embodiments, the formation of inner spacers 44 includes depositing a conformal dielectric layer, which extends into the lateral recesses 41 (FIG. 7B). Next, an etching process (also referred to as a spacer trimming process) is performed to trim the portions of the spacer layer outside of the lateral recesses 41, leaving the portions of the spacer layer in the lateral recesses 41. The remaining portions of the spacer layer are referred to as inner spacers 44. Inner spacers may be single-layer spacers, or may include a plurality of sub layers (such as two to three sub layers).

In accordance with alternative embodiments, inner spacers 44 are not formed, and the subsequently formed source/drain regions may be in contact with the high-k dielectric layers in the replacement gate stacks. A source/drain region means the corresponding region may be a source or drain region, and the corresponding regions may include both of source regions and drain regions.

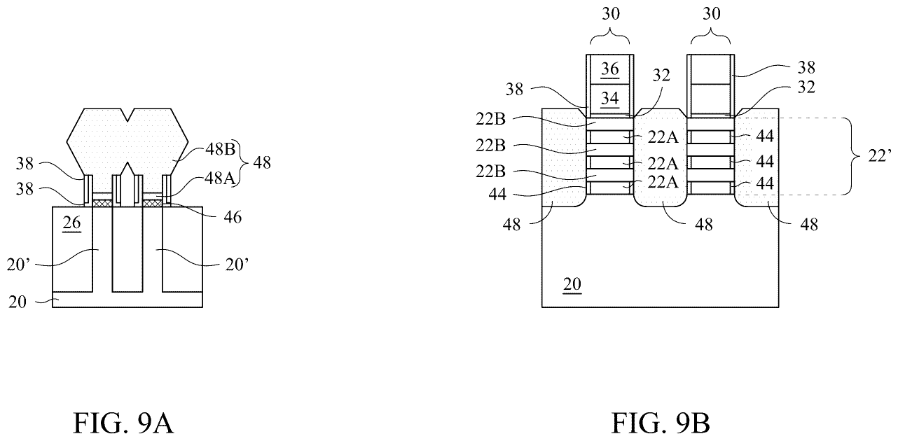

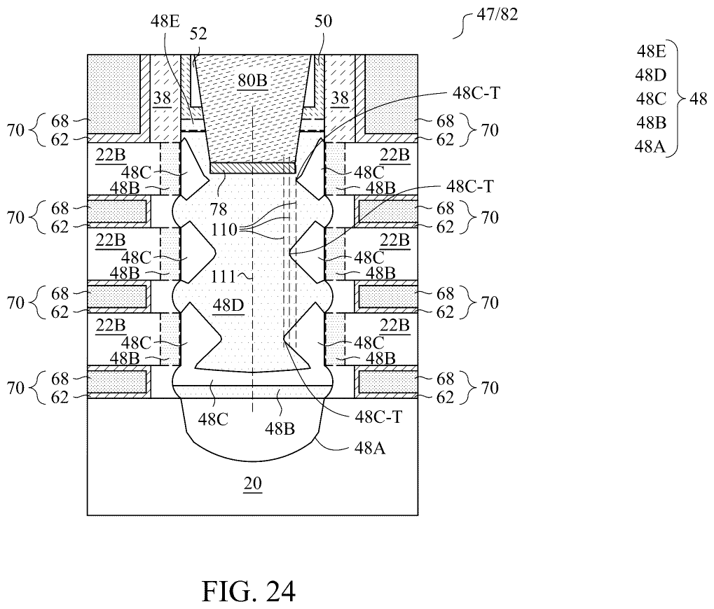

Referring to FIGS. 9A and 9B, source/drain regions 48 are formed in recesses 42, for example, through epitaxy processes. The details of source/drain regions 48 are illustrated in FIG. 24, 27, or 30 in accordance with some embodiments.

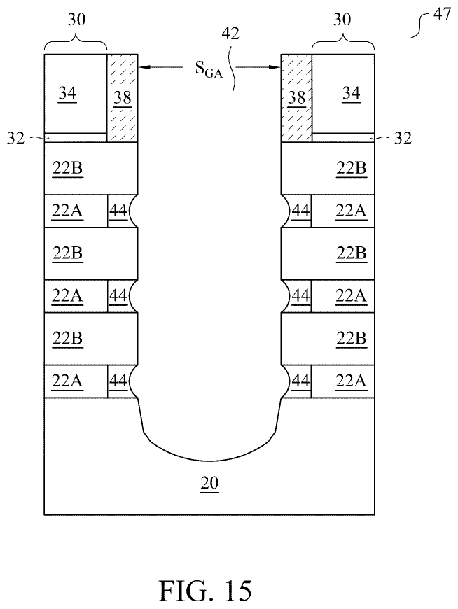

FIGS. 15-24 illustrate the details in the formation of source/drain regions 48 in accordance with some embodiments. FIG. 15 illustrates an amplified view of the region 47 in FIG. 8B, in which recesses 42 and inner spacers 44 have been formed. In accordance with some embodiments, the spacing S_{GA} between neighboring gate spacer 38 may be in the range between about 15 nm and about 25 nm. The top surface (which is a major surface) of semiconductor substrate 20 may be on a (100) surface plane or a (110) surface plane.

In the example as shown in FIG. 15, three stacked nanostructures 22B are illustrated as an example. The number of nanostructures 22B in a stack may be any other number, for example, ranging from 2 to about 5. The height (thickness) of nanostructures 22B may be in the range between about 3 nm and about 15 nm. The height (thickness) of sacrificial layers 22A (hence the height/thickness of the replacement gate stacks subsequently replacing the sacrificial layers 22A) may also be in the range between about 3 nm and about 15 nm. The pitch of the dummy gate stacks 30 may be in the range between about 30 nm and about 100 nm.

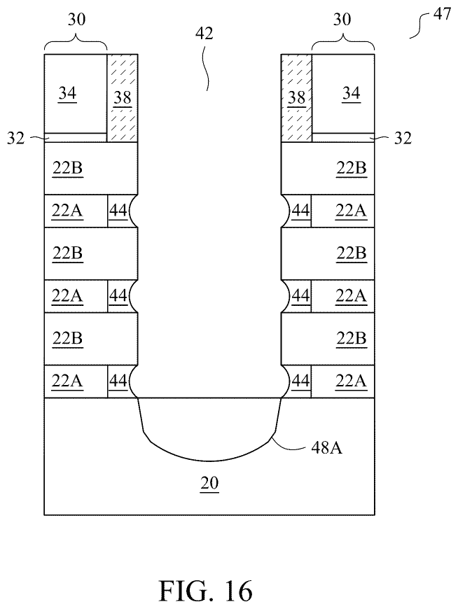

Referring to FIG. 16, separating layer 48A (also referred to as a separation layer or layer L0) is deposited, for example, through a bottom-up deposition process. The respective process is illustrated as process 216 in the process flow 200 shown in FIG. 31. Separating layer 48A may comprise silicon, and may be free elements such as germanium, carbon, and the like. Dummy separating layer 48A may also be an intrinsic layer that is free from n-type dopants (such as phosphorous, arsenic, and antimony) and p-type dopants (such as boron, indium, and the like). In accordance with alternative embodiments, separating layer 48A may comprise an n-type or p-type dopant, which is of the same conductivity type as the subsequently formed source/drain regions 48. If doped, the dopant concentration of the n-type or p-type dopant may be lower than that in the subsequently deposited layers of source/drain regions 48.

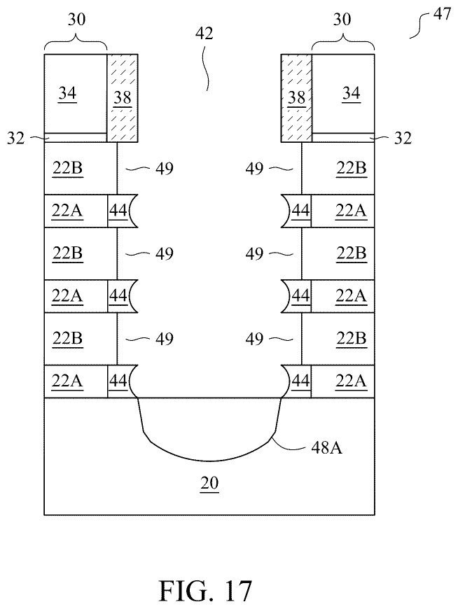

FIG. 17 illustrates the lateral recessing of nanostructures 22B to form lateral recesses 49 in accordance with some embodiments. The respective process is illustrated as process 218 in the process flow 200 shown in FIG. 31. The lateral recessing may be performed through an isotropic etching process, for example, by using an etching chemical that attacks the nanostructures 22B, but not other exposed features such as inner spacers 44. After the lateral recessing processes, the outer edges of nanostructures 22B may be directly underlying (and overlapped by) gate spacers 38, and may overlap some of inner spacers 44 and/or overlapped by some other inner spacers 44. In accordance with alternative embodiments, the lateral recessing process is skipped.

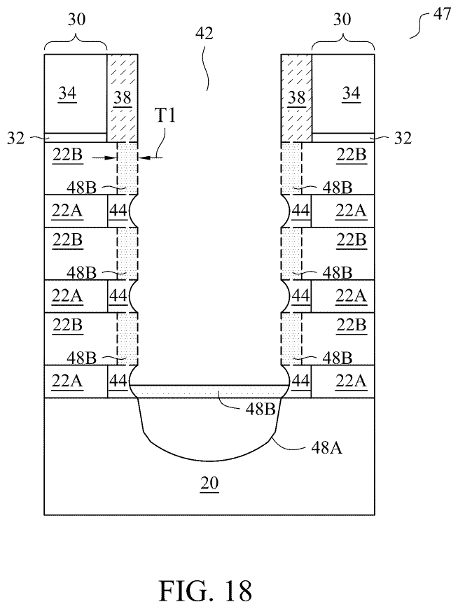

FIG. 18 illustrates the selective epitaxy of semiconductor layers 48B to fill the lateral recesses 49 (when the lateral recessing process is formed). The respective process is illustrated as process 220 in the process flow 200 shown in FIG. 31. In accordance with some embodiments, the semiconductor layers 48B comprise silicon and a dopant. The dopant is of a same conductivity type as the conductivity type of the respective transistor. For example, when the transistor is a p-type transistor, the dopant may be a p-type dopant, and may comprise boron, indium, and/or the like. Otherwise, when the transistor is an n-type transistor, the dopant may be an n-type dopant, and may comprise phosphorous, arsenic, antimony, and/or the like.

In subsequent discussion, the materials and concentrations of a p-type transistors are used as examples, and boron is discussed as an example of the dopant. While the details of the materials and concentrations of the materials corresponding to n-type transistors are not specifically discussed, one of ordinary skill in the art is able to understand the corresponding materials and concentrations. For example, the concentrations of the n-type dopant of the n-type source/drain region may be in the same range as the corresponding parts of the p-type source/drain region.

In accordance with some embodiments, semiconductor layers 48B may comprise silicon boron, and may be free from germanium therein. The boron concentration of semiconductor layers 48B may be in the range between about 3.5E20/cm³ and about 1.5E21/cm³. The thickness Ti of semiconductor layers 48B may be in the range between about 4 nm and about 7 nm. The formation of semiconductor layers 48B has the function of replacing the damaged edge portions (for example, caused by plasma, cleaning, or the like) of nanostructure 22B with an undamaged epitaxy layer, and further has the function of improving the junction control since the higher-doped semiconductor layers 48B are formed closer to the channels.

At the same time semiconductor layers 48B are formed in lateral recesses 49, a semiconductor layer 48B is also formed at the bottom of recess 42, and is grown from the top surface of separating layer 48A.

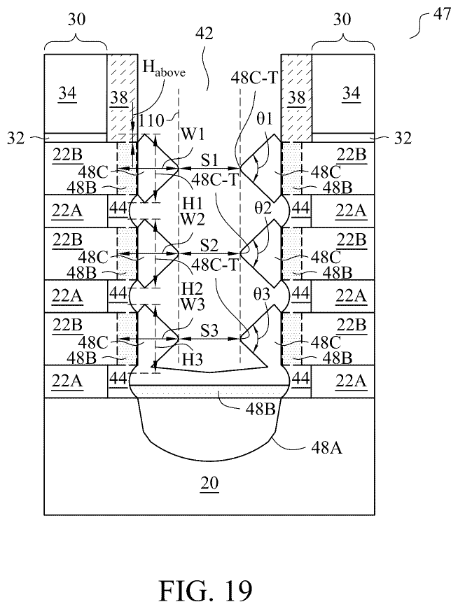

FIG. 19 illustrates the epitaxy of semiconductor layers 48C (also referred to as layer-1 or L1) through a selective epitaxy process. The respective process is illustrated as process 222 in the process flow 200 shown in FIG. 31. The resulting semiconductor layers 48C are selectively grown from separating layer 48A or the sidewalls of nanostructures 22B (if separating layer 48A is not formed). Semiconductor layers 48C may also be grown from the exposed sidewall surfaces of semiconductor layers 48B. In accordance with some embodiments in which the top surface of semiconductor substrate 20 is on a (100) surface plane, the sidewall surface of the semiconductor layers 48B may be on (110) surface planes. On the other hand, no portion (or significantly low amount) of semiconductor layers 48C is grown directly starting from the dielectric features such as the sidewalls of inner spacers 44, gate spacers 38, and hard mask 36 (refer to FIG. 9).

When the source/drain region is a p-type region of a p-type transistor, semiconductor layers 48C may comprise silicon, SiGe, or Ge, and further includes a p-type dopant such as boron, indium, or combinations thereof. For example, semiconductor layers 48C may comprise SiGe, with boron being doped. The semiconductor layers 48C may have a p-type dopant concentration in a range between about 1E20/cm³ and about 2E20/cm³. The thickness of semiconductor layers 48C may be smaller than about 10 nm. The boron concentration may be higher than that in semiconductor layers 48B, for example, with a ratio of the boron concentration in semiconductor layers 48C to the boron concentration in semiconductor layers 48B being in the range between about 1.5 and about 5. The germanium atomic percentage may be in the range between about 0 percent and about 40 percent.

In accordance with some embodiments, the lateral recessing of nanostructures 22B are skipped, and thus the semiconductor layers 48C are directly grown from the un-recessed sidewalls of nanostructures 22B. In accordance with yet alternative embodiments in which nanostructures 22B are laterally recessed, semiconductor layers 48C may fill the lateral recesses 49 (FIG. 17) to contact the semiconductor nanostructures 22B.

The selective formation process may include a plurality of cycles, each including a deposition process and an etch-back process. In the deposition processes of the cycles, the thickness of semiconductor layer 48C is increased, while in the etch-back processes of the cycles, the thickness of semiconductor layers 48C is reduced. The plurality of cycles are also referred to as deposition-and-etch cycles. In accordance with some embodiments, the etch-back process is performed through an isotropic etching process, with no bias power applied. The etching gas may include HCl, Cl₂, or the like, or combinations thereof.

After the deposition of semiconductor layers 48C, an additional etch-back process may be performed to etch-back semiconductor layers 48C if the semiconductor layers 48C have some portions deposited on dielectric features. The additional etch-back process may be performed through an isotropic etching process, with no bias power applied. The etching gas may include HCl, Cl₂, or the like, or combinations thereof. Otherwise, if no semiconductor layer 48C is grown to cover the dielectric materials, the additional etch-back process may be skipped.

As shown in FIG. 19, In accordance with some embodiments, there may be a plurality of discrete semiconductor layers 48C that are separated from each other, each epitaxially grown from one of nanostructure 22B. The semiconductor layers 48C may have similar (and/or the same) sizes and shapes. Also, the upper ones of the semiconductor layers 48C may have the same sizes, and extend laterally into recess 42 for same distances as the respective lower ones of the semiconductor layers 48C. For example, dashed lines 110 are drawn to show that the front ends (tips) of semiconductor layers 48C are vertically aligned.

In accordance with some embodiments, the lateral spacings S1, S2, and S3 of semiconductor layers 48C grown from different nanostructures 22B are close to, and may be equal to each other within process variation. The heights H1, H2, and H3 of semiconductor layers 48C on different nanostructures 22B may be close to, and may be equal to each other within process variation. The widths W1, W2, and W3 of semiconductor layers 48C on different nanostructures 22B may be close to, and may be equal to each other within process variation. Furthermore, the topmost ends of semiconductor layers 48C may be higher than the top surface of the respective nanostructure 22B by height difference H_{above}, which may have a positive value, and may be in the range between about 1 nm and about 5 nm. The tips 48C-T of semiconductor layers 48C may be level with the middle level between the top surface and the bottom surface of the respective nanostructure 22B.

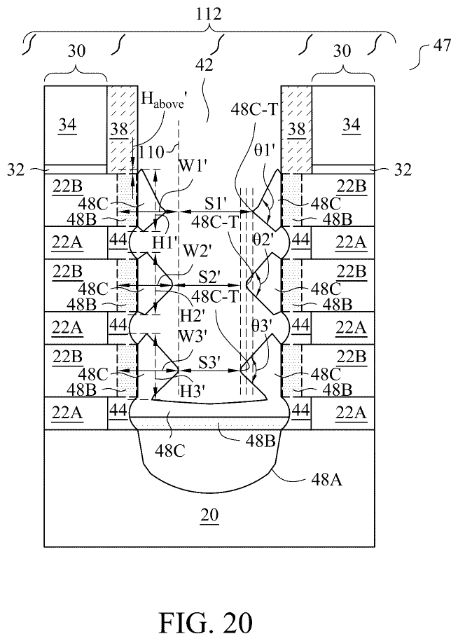

FIG. 20 illustrates the shaping process 112 for shaping semiconductor layers 48C in accordance with some embodiments. The respective process is illustrated as process 224 in the process flow 200 shown in FIG. 31. The shaping is performed to reduce the sizes of the top semiconductor layers 48C that are grown from the top semiconductor nanostructures 22B. The lower semiconductor layers 48C, on the other hand, are reduced less in size than the top semiconductor layers 48C.

In accordance with some embodiments, the shaping process 112 comprises an etching process. The etching gas may include HCl, Cl₂, and/or a halogen etching gas such as F₂, CF₄, or the like. The etching process may comprise a thermal etching process, and/or a plasma etching process. In the thermal etching process, the wafer may be heated. The temperature of the wafer may be related to the etching gas used. For example, when HCl is used as the etching gas, the wafer temperature may be in the range between about 350° C. and about 1,0000° C. The flow rate of HCl may be in the range between about 5 Torr and about 300 Torr.

When Cl₂ is used as the etching gas, the wafer temperature may be in the range between about 200° C. and about 500° C. The flow rate of Cl₂ may be in the range between about 5 Torr and about 100 Torr. When a halogen gas is used as the etching gas, the wafer temperature may be in the range between about 200° C. and about 800° C. The flow rate of the halogen gas may be in the range between about 5 Torr and about 300 Torr.

In accordance with some embodiments, the shaping process 112 is a process separate from the etch-back processes in the formation of semiconductor layers 48C. The shaping process 112 may be started after the etch-back is stopped. The shaping process 112 may be performed using a different etching gas and/or different process conditions (such as different flow rates and partial pressure of the etching gases) than the etch-back processes. For example, the wafer temperature in the shaping process 112 may be higher than, equal to, or lower than, the wafer temperature in the etch-back processes.

Furthermore, the shaping process 112 may be performed with a bias power applied. The bias power may be in the range between about 20 watts and about 60 watts. In accordance with alternative embodiments, the shaping process 112 may be performed without the bias power.

Due to the difference between the etching rates at the top of recess 42 and the bottom of recess 42, further because the likely bias power, the upper semiconductor layers 48C may act as the shades of the respective underlying semiconductor layers 48C, so that the lower semiconductor layers 48C are etched less than the respective overlying semiconductor layers 48C. In accordance with some embodiments, as shown in FIG. 20, after the shaping process 112 is finished, the spacings S1′, S2′, and S3′ are smaller than the respective spacings S1, S2, and S3 (FIG. 19), respectively. The widths W1′, W2′, and W3′ may be smaller than the respective spacings W1, W2, and W3 (FIG. 19), respectively. The heights H1′, H2′, and H3′ may be smaller than the respective spacings H1, H2, and H3 (FIG. 19), respectively.

Furthermore, the dimension change of upper semiconductor layers 48C are more significant than the dimension change of the respective lower semiconductor layers 48C. For example, there may exist the relationship (S1′-S1)>(S2′-S2)>(S3′-S3), the relationship (W1-W1′)>(W2-W2′)>(W3-W3′), and/or the relationship (H1-H1′)>(H2-H2′)>(H3-H3′).

In accordance with some embodiments, after the shaping process 112, the topmost ends of semiconductor layers 48C may be higher than the top surface of the respective nanostructure 22B by height difference H_{above}′, which may have a positive value, equal to zero, or have a negative value (when the topmost end is actually lower than the top surface of the respective nanostructure 22B). For example, the height difference H_{above}′ may be in the range between about +5 nm and about −5 nm.

The tips 48C-T of the top semiconductor layers 48C may be level with or lower than the middle point between the top surface and the bottom surface of the respective nanostructure 22B. In accordance with some embodiments, the tips 48C-T of the top semiconductor layers 48C may be lower than the top surfaces of the respective semiconductor layers 48C by height difference H_{above}′, which may be in the range between about 3 nm and about 8 nm.

In accordance with some embodiments, the top semiconductor layers 48C may include bird beaks 114, which are the up-rising portions protruding from the respective straight upper facets. The top semiconductor layers 48C may include upper facets and lower facets joined at the tips 48C-T. The upper facets of the top semiconductor layers 48C may be longer than the respective lower facets.

The bottom semiconductor layers 48C may not include bird beaks. The bottom semiconductor layers 48C may include upper facets and lower facets joined at the tips 48C-T. The upper facets of bottom semiconductor layers 48C may have the same lengths as the respective lower facets. The tips 48C-T of the bottom semiconductor layers 48C may be at the same level as the middle height of the bottom ones of the nanostructures 22B.

In accordance with some embodiments, the tip angles of semiconductor layers 48C are increased by the shaping process 112. For example, the tip angles may exist the relationships θ1′>θ1, θ2′>θ2, and θ3′>=θ3 (refer to FIGS. 19 and 20). The increase in the tip angles of the upper semiconductor layers 48C may be greater than the increase in the tip angles of the respective lower semiconductor layers 48C. For example, there may exist the relationship (θ1′-θ1)>(θ2′-θ2)>(θ3′-θ3). In accordance with some embodiments, before the shaping process 112, the tip angles θ1, θ2, and θ3 (FIG. 19) are acute angles, while after the shaping process 112, the tip angles θ1′ (FIG. 20) is an obtuse angle, while tip angles θ2′ and θ3′ may be acute angles or obtuse angles.

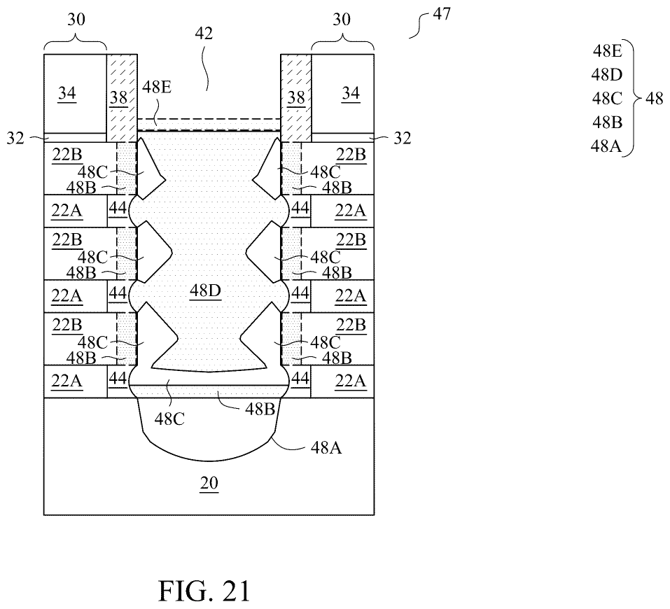

FIG. 21 illustrates the epitaxy growth of semiconductor layer 48D (also referred to as semiconductor layer-2 or L2). The respective process is illustrated as process 226 in the process flow 200 shown in FIG. 31. The resulting semiconductor layer 48D is grown from, and is different from, semiconductor layers 48C. In accordance with some embodiments, semiconductor layer 48D has a higher p-type dopant (such as boron) doping concentration than semiconductor layers 48C. For example, the boron concentration in semiconductor layer 48D may be in a range between about 5E20/cm³ and about 3E21/cm³.

Semiconductor layer 48D may comprise SiGe with a germanium atomic percentage higher than the germanium atomic percent of semiconductor layers 48C. For example, the germanium atomic percentage in semiconductor layer 48D may be in the range between about 20 percent and about 70 percent. The top surface of semiconductor layer 48D is higher than the topmost ends of semiconductor layers 48C and the topmost surfaces of the topmost nanostructures 22B.

FIG. 21 further illustrates the formation of capping layer 48E in accordance with some embodiments, for example, through a selective epitaxy process. The respective process is illustrated as process 228 in the process flow 200 shown in FIG. 31. In accordance with some embodiments, capping layer 48E comprises silicon free from germanium. Capping layer 48E may also include SiGe with a lower germanium atomic percentage than that in semiconductor layers 48D and 48C. The boron concentration in capping layer 48E may also be lower than the boron concentration in semiconductor layer 48D, for example, by one order or more. In accordance with alternative embodiments, capping layer 48E is not formed. Accordingly, capping layer 48E is illustrated as being dashed to indicate that it may be, or may not be, formed.

Throughout the description, separating layer 48A and semiconductor layers 48B, 48C, 48D, and 48E are collectively referred to as source/drain regions 48. Semiconductor layer 48C and 48D are also referred to as a lower-dopant-concentration layer and a higher-dopant-concentration layer, respectively, due to their difference in the p-type dopant (such as boron) concentrations.

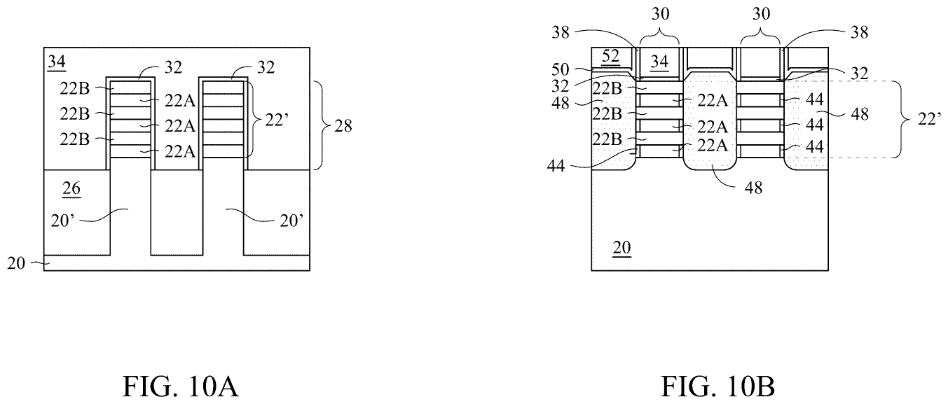

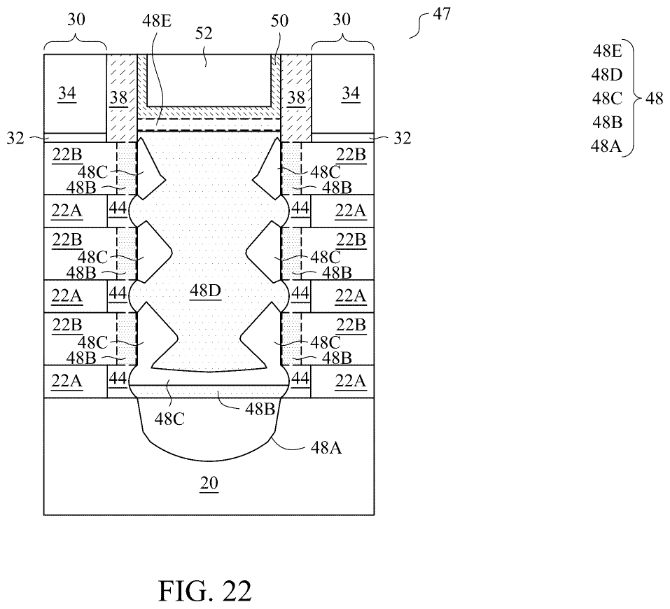

FIGS. 10A and 10B illustrate the cross-sectional views of the structure after the formation of Contact Etch Stop Layer (CESL) 50 and Inter-Layer Dielectric (ILD) 52. The respective process is illustrated as process 230 in the process flow 200 shown in FIG. 31. The corresponding structure is also shown in FIG. 22. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may be silicon oxide, Phospho-Silicate Glass (PSG), Boro-Silicate Glass (BSG), Boron-Doped Phospho-Silicate Glass (BPSG), Undoped Silicate Glass (USG), or the like.

CESL 50 and ILD 52 are planarized through a planarization process such as a CMP process or a mechanical grinding process. In accordance with some embodiments, the planarization process may remove hard masks 36 to reveal dummy gate electrodes 34, as shown in FIG. 10A. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

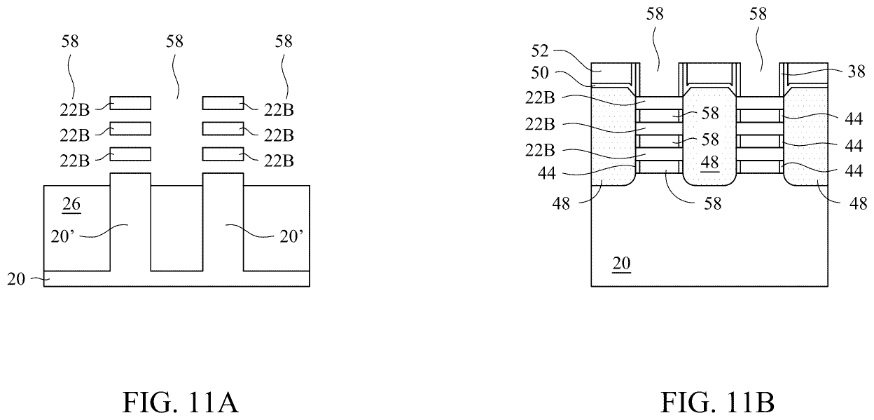

Next, dummy gate electrodes 34 and dummy gate dielectrics 32 (and hard masks 36, if remaining) are removed in one or more etching processes, so that recesses are formed, as shown in FIGS. 11A and 11B. The respective process is illustrated as process 232 in the process flow 200 shown in FIG. 31.

Sacrificial layers 22A are then removed to extend recesses 58 between nanostructures 22B. The respective process is illustrated as process 234 in the process flow 200 shown in FIG. 31. Sacrificial layers 22A may be removed by performing an isotropic etching process such as a wet etching process using etchants which are selective to the materials of sacrificial layers 22A, while nanostructures 22B, substrate 20, and STI regions 26 remain relatively un-etched as compared to sacrificial layers 22A.

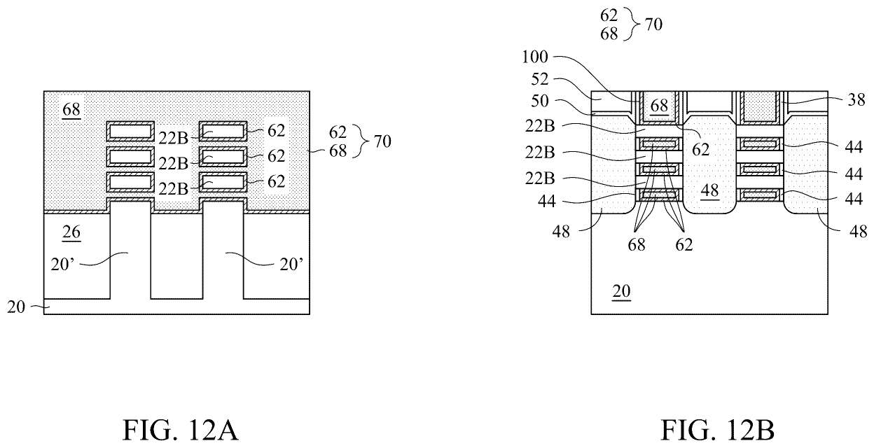

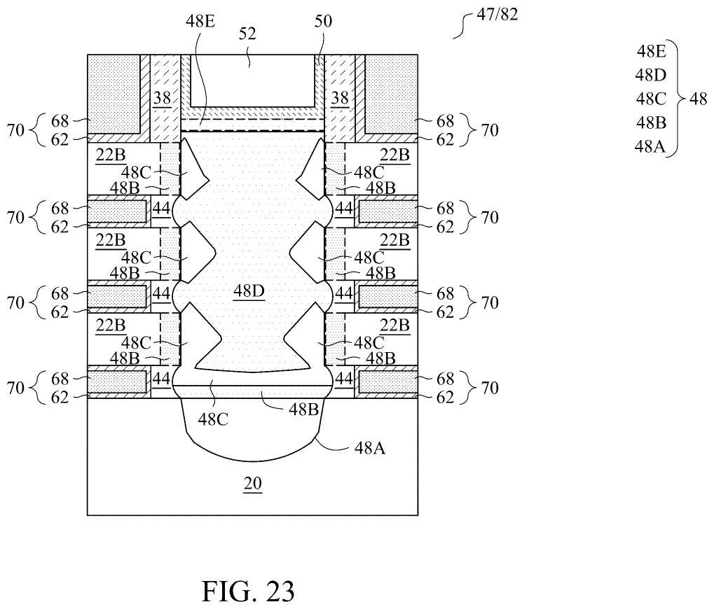

Referring to FIGS. 12A and 12B, gate dielectrics 62 and gate electrodes 68 are formed, hence forming replacement gate stacks 70. The respective process is illustrated as process 236 in the process flow 200 shown in FIG. 31. The corresponding structure is also shown in FIG. 23. In accordance with some embodiments, each of gate dielectric 62 includes an interfacial layer and a high-k dielectric layer on the interfacial layer. The interfacial layer may be formed of or comprises silicon oxide. In accordance with some embodiments, the high-k dielectric layer comprises one or more dielectric layers. For example, the high-k dielectric layer may include a metal oxide or a silicate of hafnium, aluminum, zirconium, lanthanum, manganese, barium, titanium, lead, and combinations thereof.

Gate electrodes 68 are also formed. In the formation process, conductive layers are first formed on the high-k dielectric layer, and the remaining portions of recesses 58 are filled. Gate electrodes 68 may include a metal-containing material such as TiN, TaN, TiAl, TiAlC, cobalt, ruthenium, aluminum, tungsten, combinations thereof, and/or multilayers thereof.

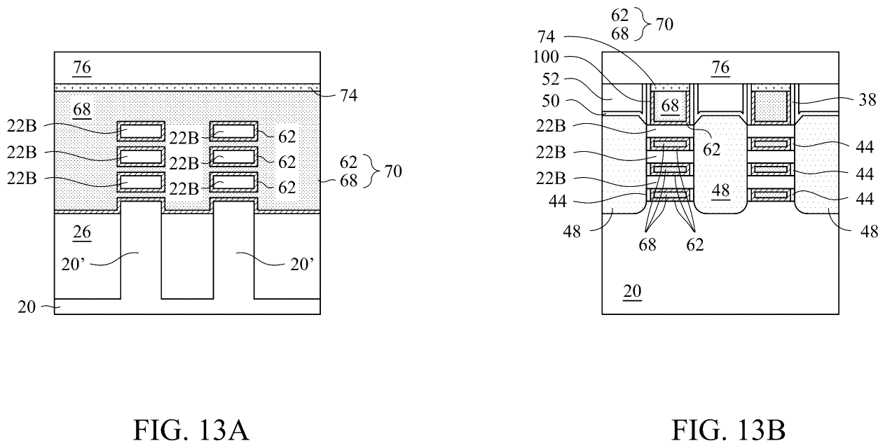

In the processes shown in FIGS. 13A and 13B, gate stacks 70 are recessed, so that recesses are formed directly over gate stacks 70 and between opposing portions of gate spacers 38. A gate mask 74 comprising one or more layers of dielectric material, such as silicon nitride, silicon oxynitride, or the like, is filled in each of the recesses, followed by a planarization process to remove excess portions of the dielectric material extending over ILD 52. The respective process is illustrated as process 238 in the process flow 200 shown in FIG. 31.

As further illustrated by FIGS. 13A and 13B, ILD 76 is deposited over ILD 52 and over gate masks 74. The respective process is illustrated as process 240 in the process flow 200 shown in FIG. 31. An etch stop layer (not shown) may be (or may not be) deposited before the formation of ILD 76. In accordance with some embodiments, ILD 76 is formed through FCVD, CVD, PECVD, or the like. ILD 76 is formed of a dielectric material, which may be selected from silicon oxide, PSG, BSG, BPSG, USG, or the like.

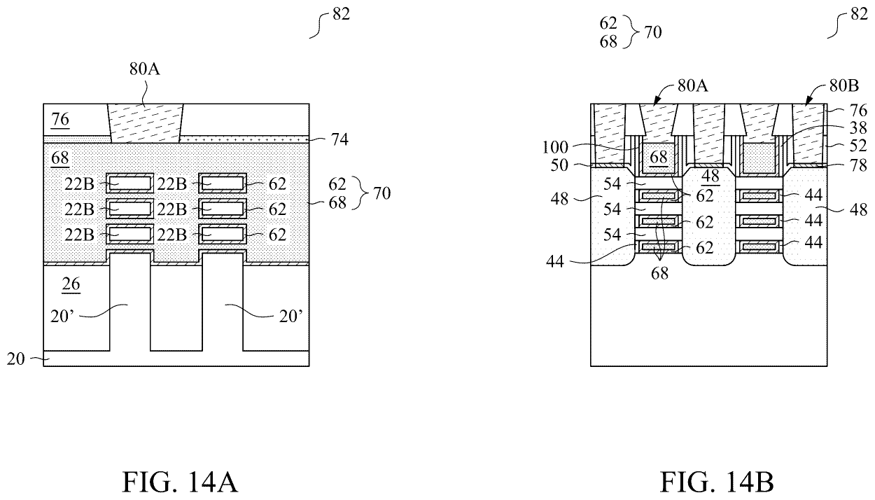

In FIGS. 14A and 14B, ILD 76, ILD 52, CESL 50, and gate masks 74 are etched to form recesses (occupied by contact plugs 80A and 80B) exposing surfaces of source/drain regions 48 and/or gate stacks 70. The recesses may be formed through etching using an anisotropic etching process, such as RIE, NBE, or the like. Although FIG. 14B illustrates that contact plugs 80A and 80B are in a same cross-section, in various embodiments, contact plugs 80A and 80B may be formed in different cross-sections, thereby reducing the risk of shorting with each other.

After the recesses are formed, silicide regions 78 are formed over source/drain regions 48. The respective process is illustrated as process 242 in the process flow 200 shown in FIG. 31. Contact plugs 80B are then formed over silicide regions 78. Also, contacts 80A (may also be referred to as gate contact plugs) are also formed in the recesses, and are over and contacting gate electrodes 68. The respective process is illustrated as process 244 in the process flow 200 shown in FIG. 31. The corresponding structure is also shown in FIG. 24. Transistor 82 is thus formed. It is noted that the details of the source/drain regions 48 are not shown in FIGS. 14A and 14B, and the details may be found referring to FIG. 24.

FIG. 24 illustrates parts of the transistor 82, which is also shown in FIGS. 14A and 14B. It is appreciated that if the shaping process of semiconductor layers 48C is not performed, some parts of silicide regions 78 and (source/drain) contact plug 80B (also referred to as contact structure 80B) may land on semiconductor layers 48C rather than semiconductor layer 48D. Semiconductor layer 48D has a higher boron doping concentration than semiconductor layers 48C. Silicide region 78 has a conductivity value greater than that of semiconductor layer 48D and lower than that of contact plug 80B.

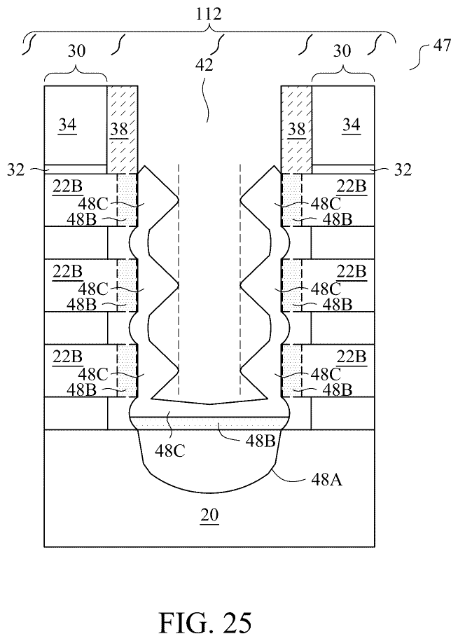

FIGS. 25 through 27 illustrate the formation of GAA transistor 82 in accordance with alternative embodiments. These embodiments are essentially the same as the preceding embodiments, except that neighboring semiconductor layers 48C may be merged. Unless specified otherwise, the materials, the structures, and the formation processes of the components in these embodiments (and subsequent embodiments) are essentially the same as the like components denoted by like reference numerals in the preceding embodiments. The details regarding the materials, the structures, and the formation processes provided in each of the embodiments throughout the description may be applied to any other embodiment whenever applicable.

The initial steps of these embodiments are essentially the same as shown in FIGS. 1-8A/8B and 15-18. Next, as shown in FIG. 25, semiconductor layer 48C is formed. The portions of the semiconductor layers 48C grown from neighboring nanostructures 22B may be merged to form a continuous semiconductor layer 48C. The portions of semiconductor layer 48C grown from neighboring nanostructures 22B may have the same size before and after the merging.

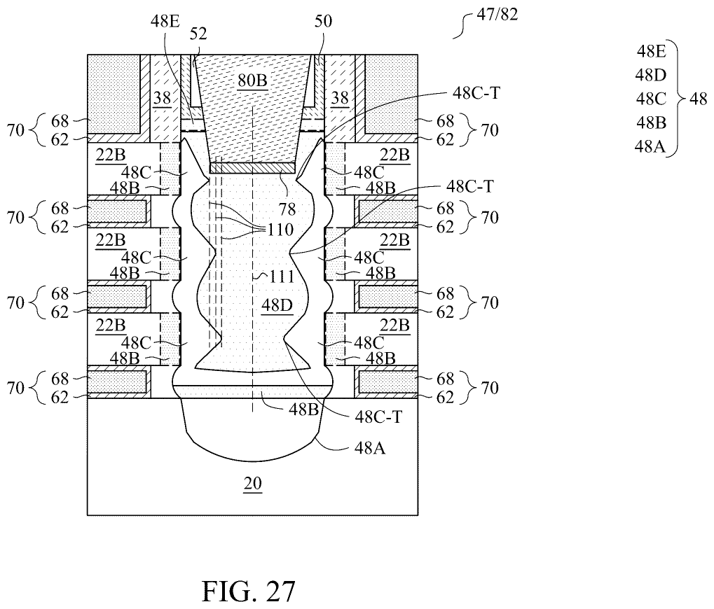

In accordance with alternative embodiments in which inner spacers 44 are not formed, semiconductor layer 48C is grown from both of semiconductor nanostructures 22B and sacrificial layers 22A. This will also cause that in the final transistors, for example, as shown in FIG. 27, the semiconductor layer 48C may be in contact with the gate dielectrics 62. For example, when inner spacers 44 are not formed, the semiconductor layer 48C may be in contact with the high-k dielectric layers of the gate dielectrics 62 when the interfacial layers are formed through oxidation. Alternatively, the semiconductor layer 48C may be in contact with the interfacial layers of the gate dielectrics 62 when the interfacial layers are formed through deposition processes.

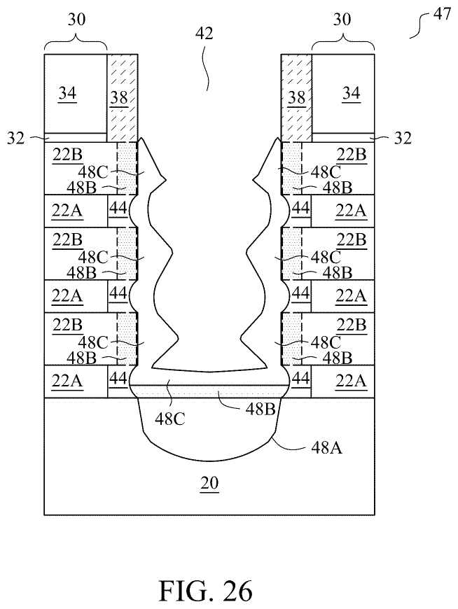

FIG. 25 further illustrates the shaping process 112. After the shaping process 112, the upper portions of semiconductor layer 48C grown from upper nanostructures 22B are reduced in size, and are smaller than the respective lower portions of semiconductor layer 48C grown from lower nanostructures 22B. The resulting structure is shown in FIG. 26. The sizes and the changes of the sizes are essentially the same as discussed referring to (and may be realized from) FIGS. 19 and 20, and are not repeated herein. FIG. 27 illustrates the formation of upper features to finish the formation of transistor 82.

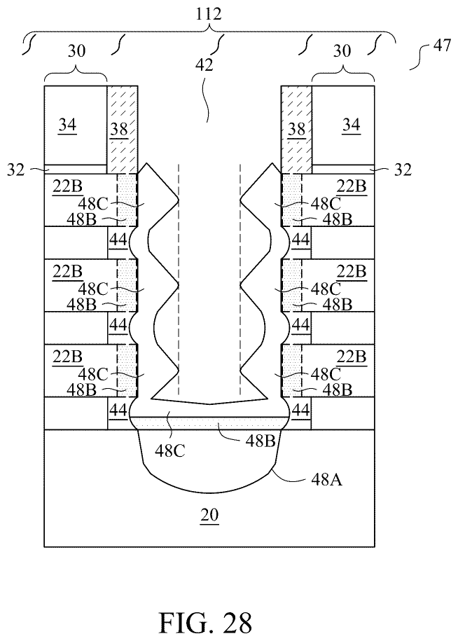

FIGS. 28 through 30 illustrate the formation of GAA transistor 82 in accordance with yet alternative embodiments. These embodiments are essentially the same as the preceding embodiments, except that in the shaping process 112, the bottom portion of semiconductor layer 48B is etched-through to expose the underlying separating layer 48A.

The initial steps of these embodiments are essentially the same as shown in FIGS. 1-8A/8B and 15-18. The resulting structure is essentially the same as what is shown in FIG. 26, with the semiconductor layers 48C being merged to form a continuous layer.

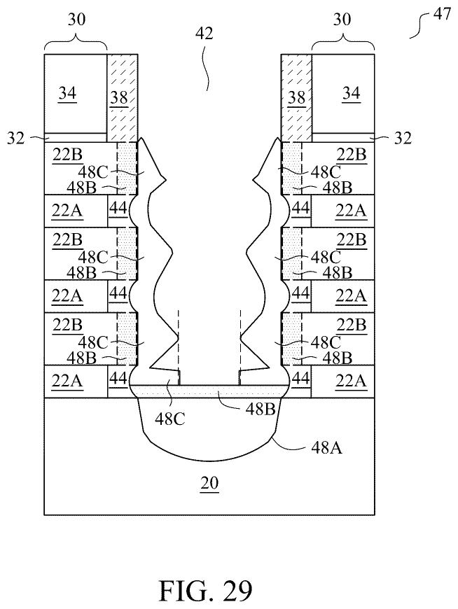

FIG. 28 illustrates the shaping process 112. After the shaping process 112, the upper portions of semiconductor layer 48C grown from upper nanostructures 22B are etched, and hence are smaller than the respective lower portions of semiconductor layer 48C grown from lower nanostructures 22B. The resulting structure is shown in FIG. 29. The sizes are essentially the same as discussed referring to (and may be realized from) FIGS. 19 and 20, and are not repeated herein. The shaping process 112, for example, due to the bias power applied, may cause the etch-through of the bottom part of semiconductor layer 48C. The tips of the bottom ones of semiconductor layers 48C may be vertically aligned to the edges of the semiconductor layer 48C at the bottom of recess 42. Semiconductor layer 48B may or may not be etched-through.

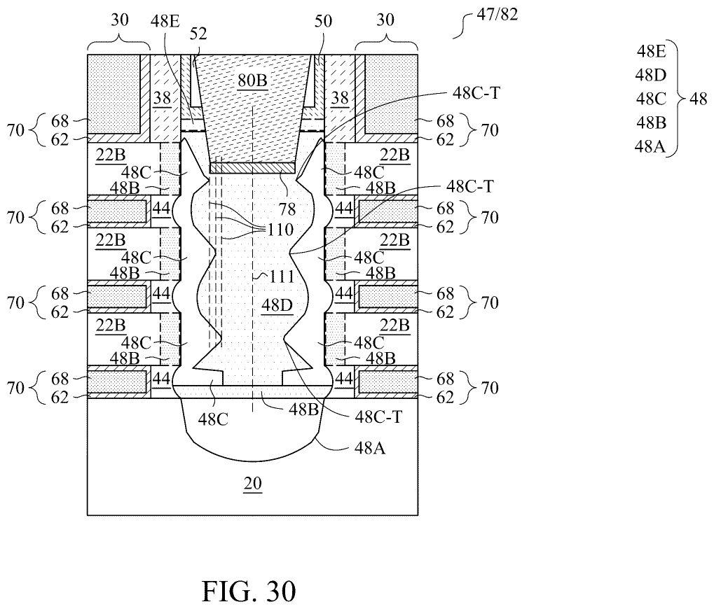

FIG. 30 illustrates the formation of upper features to finish the formation of transistor 82. Due to the etch-through of the bottom part of semiconductor layer 48B, semiconductor layer 48D penetrates through semiconductor layer 48B to contact semiconductor layers 48B. Alternatively, semiconductor layer 48D may penetrate through semiconductor layers 48C and 48B (if semiconductor layer 48B is also etched through) to contact separating layer 48A.

FIGS. 24, 27, and 30 illustrate some dashed vertical lines, wherein the positions of the end tips of the semiconductor layers 48C are aligned to the dashed vertical lines. The dashed vertical lines illustrate that the lower semiconductor layers 48C are larger, and extend more toward the middle center line 111 of the respective source/drain region 48 than the respective upper semiconductor layers 48C.

The embodiments of the present disclosure have some advantageous features. By shaping the top ones of lower-dopant-concentration layers, it is easier for the source/drain contact plugs and silicide layers to land on higher-dopant-concentration layer. The contact resistance is thus reduced, and the process window is also enlarged.

In accordance with some embodiments of the present disclosure, a method comprises forming a plurality of semiconductor nanostructures, wherein upper ones of the plurality of semiconductor nanostructures overlap respective lower ones of the plurality of semiconductor nanostructures; forming a plurality of semiconductor layers, each from one of the plurality of semiconductor nanostructures; shaping the plurality of semiconductor layers through an etching process, wherein a first semiconductor layer of the plurality of semiconductor layers is etched more than a second semiconductor layer of the plurality of semiconductor layers, and wherein the first semiconductor layer is higher than the second semiconductor layer; and after the plurality of semiconductor layers are shaped, forming an additional semiconductor layer electrically connected to the plurality of semiconductor layers.

In an embodiment, in the shaping the plurality of semiconductor layers, a third semiconductor layer of the plurality of semiconductor layers is etched less than the second semiconductor layer. In an embodiment, the etching process is performed with a bias power applied. In an embodiment, a portion of the second semiconductor layer extends laterally beyond a tip of the first semiconductor layer. In an embodiment, the plurality of semiconductor layers are formed in a recess that is formed between the plurality of semiconductor nanostructures and additional plurality of semiconductor nanostructures.

In an embodiment, when the plurality of semiconductor layers are formed, a bottom semiconductor layer is formed at a bottom of the recess, and wherein in the shaping, a through-opening is formed in the bottom semiconductor layer. In an embodiment, when the plurality of semiconductor layers are formed, a bottom semiconductor layer is formed at a bottom of the recess, and wherein at a time after the shaping, the bottom semiconductor layer covers an entirety of the bottom of the recess. In an embodiment, the plurality of semiconductor layers are physically separated from each other.

In an embodiment, the plurality of semiconductor layers are joined as a continuous semiconductor layer. In an embodiment, the forming the plurality of semiconductor layers comprises a deposition process and an etch-back process following the deposition process, and wherein the etch-back process and the shaping are separate processes.

In accordance with some embodiments of the present disclosure, a structure comprises a semiconductor stack comprising a plurality of semiconductor nanostructures; a source/drain region comprising a plurality of semiconductor layers at same levels as respective ones of the plurality of semiconductor nanostructures, wherein upper ones of the plurality of semiconductor layers are smaller than respective lower ones of the plurality of semiconductor layers; and an additional semiconductor layer joined to the plurality of semiconductor layers; and a gate stack comprising portions between the plurality of semiconductor nanostructures.

In an embodiment, a first semiconductor layer of the plurality of semiconductor layers is higher than a second semiconductor layer of the plurality of semiconductor layers, and wherein the second semiconductor layer extends laterally beyond a tip of the first semiconductor layer. In an embodiment, each of lower ones of the plurality of semiconductor layers is laterally wider than all overlying ones of the plurality of semiconductor layers. In an embodiment, a topmost one of the plurality of semiconductor layers comprises a first upper facet and a first lower facet, and wherein the first upper facet is longer than the first lower facet in a cross-section of the structure.

In an embodiment, a bottommost one of the plurality of semiconductor layers comprises a second upper facet and a second lower facet, and wherein the second upper facet has a same length as the second lower facet in the cross-section of the structure. In an embodiment, a first tip of a topmost semiconductor layer of the plurality of semiconductor layers is lower than a first middle line between a first top surface and a first bottom surface of the topmost semiconductor layer.

In an embodiment, a second tip of a bottommost semiconductor layer of the plurality of semiconductor layers is level with a second middle line between a second top surface and a second bottom surface of the bottommost semiconductor layer.

In accordance with some embodiments of the present disclosure, a structure comprises a first semiconductor stack comprising a first plurality of semiconductor nanostructures; a second semiconductor stack comprising a second plurality of semiconductor nanostructures; a source/drain region between the first semiconductor stack and the second semiconductor stack, the source/drain region comprising a layer-2 semiconductor layer comprising a portion at a middle of the source/drain region; a first plurality of layer-1 semiconductor layers between the layer-2 semiconductor layer and the first plurality of semiconductor nanostructures; and a second plurality of layer-1 semiconductor layers between the layer-2 semiconductor layer and the second plurality of semiconductor nanostructures, wherein a first topmost layer-1 semiconductor layer of the first plurality of layer-1 semiconductor layers is spaced apart from a second topmost layer-1 semiconductor layer of the second plurality of layer-1 semiconductor layers by a first lateral distance, and a first bottommost layer-1 semiconductor layer of the first plurality of layer-1 semiconductor layers is spaced apart from a second bottommost layer-1 semiconductor layer of the second plurality of layer-1 semiconductor layers by a second lateral distance smaller than the first lateral distance.

In an embodiment, a first intermediate layer-1 semiconductor layer of the first plurality of layer-1 semiconductor layers is spaced apart from a second intermediate layer-1 semiconductor layer of the second plurality of layer-1 semiconductor layers by a third distance, and wherein the third distance is smaller than the first lateral distance and greater than the second lateral distance. In an embodiment, in a cross-sectional view of the structure, lower ones of the first plurality of layer-1 semiconductor layers are increasingly larger than respective upper ones of the first plurality of layer-1 semiconductor layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a plurality of semiconductor nanostructures, wherein upper ones of the plurality of semiconductor nanostructures overlap respective lower ones of the plurality of semiconductor nanostructures;
forming a plurality of semiconductor layers, each from one of the plurality of semiconductor nanostructures;
shaping the plurality of semiconductor layers through an etching process; and
after the plurality of semiconductor layers are shaped, forming an additional semiconductor layer electrically connected to the plurality of semiconductor layers.

2. The method of claim 1, wherein in the shaping the plurality of semiconductor layers, a first semiconductor layer of the plurality of semiconductor layers is etched more than a second semiconductor layer of the plurality of semiconductor layers.

3. The method of claim 2, wherein a portion of the second semiconductor layer extends laterally beyond a tip of the first semiconductor layer.

4. The method of claim 1, wherein the etching process is performed with a bias power applied.

5. The method of claim 1 further comprising forming a source/drain recess that separates the plurality of semiconductor nanostructures from additional plurality of semiconductor nanostructures, wherein the plurality of semiconductor layers are formed in the source/drain recess.

6. The method of claim 5, wherein when the plurality of semiconductor layers are formed, a bottom semiconductor layer is formed at a bottom of the source/drain recess, and wherein in the shaping, a through-opening is formed in the bottom semiconductor layer.

7. The method of claim 5, wherein when the plurality of semiconductor layers are formed, a bottom semiconductor layer is formed at a bottom of the source/drain recess, and wherein at a time after the shaping, the bottom semiconductor layer covers an entirety of the bottom of the source/drain recess.

8. The method of claim 1, wherein the plurality of semiconductor layers are physically separated from each other.

9. The method of claim 1, wherein the plurality of semiconductor layers are joined as a continuous semiconductor layer, and wherein the method further comprises:
forming a replacement gate stack, wherein sidewalls of portions of the replacement gate stack are in contact with the continuous semiconductor layer.

10. The method of claim 1, wherein the forming the plurality of semiconductor layers comprises a deposition process and an etch-back process following the deposition process, and wherein the etch-back process and the shaping are separate processes.

11. A structure comprising:
a semiconductor stack comprising a plurality of semiconductor nanostructures;
a source/drain region comprising:
a plurality of semiconductor layers at same levels as respective ones of the plurality of semiconductor nanostructures, wherein upper ones of the plurality of semiconductor layers are smaller than respective lower ones of the plurality of semiconductor layers; and
an additional semiconductor layer joined to the plurality of semiconductor layers; and
a gate stack comprising portions between the plurality of semiconductor nanostructures.

12. The structure of claim 11, wherein a first semiconductor layer of the plurality of semiconductor layers is higher than a second semiconductor layer of the plurality of semiconductor layers, and wherein the second semiconductor layer extends laterally beyond a tip of the first semiconductor layer.

13. The structure of claim 11, wherein each of lower ones of the plurality of semiconductor layers is laterally wider than all overlying ones of the plurality of semiconductor layers.

14. The structure of claim 11, wherein a topmost one of the plurality of semiconductor layers comprises a first upper facet and a first lower facet, and wherein the first upper facet is longer than the first lower facet in a cross-section of the structure.

15. The structure of claim 14, wherein a bottommost one of the plurality of semiconductor layers comprises a second upper facet and a second lower facet, and wherein the second upper facet has a same length as the second lower facet in the cross-section of the structure.

16. The structure of claim 11, wherein a first tip of a topmost semiconductor layer of the plurality of semiconductor layers is lower than a first middle line between a first top surface and a first bottom surface of the topmost semiconductor layer.

17. The structure of claim 11, wherein a second tip of a bottommost semiconductor layer of the plurality of semiconductor layers is level with a second middle line between a second top surface and a second bottom surface of the bottommost semiconductor layer.

18. A structure comprising:
a semiconductor stack comprising a plurality of semiconductor nanostructures, wherein the plurality of semiconductor nanostructures comprise:
a first semiconductor nanostructure; and
a second semiconductor nanostructure overlapped by the first semiconductor nanostructure;
a source/drain region aside of the semiconductor stack, the source/drain region comprising:
a first semiconductor layer comprising a portion at a middle of the source/drain region;
a first portion of a second semiconductor layer between the first semiconductor layer and the first semiconductor nanostructure; and
a second portion of the second semiconductor layer between the first semiconductor layer and the second semiconductor nanostructure;
a source/drain silicide region over the source/drain region, wherein an electrical conductivity of the source/drain silicide region is greater than an electrical conductivity of the source/drain region; and
a source/drain contact plug over and contacting the source/drain silicide region, wherein the source/drain contact plug overlaps a portion of the second portion of the second semiconductor layer, wherein the first portion of the second semiconductor layer is laterally offset from an entirety of the source/drain contact plug, and wherein an electrical conductivity of the source/drain contact plug is greater than an electrical conductivity of the source/drain region.

19. The structure of claim 18, wherein in a cross-sectional view of the structure, the first portion of the second semiconductor layer is narrower than the second portion of the second semiconductor layer.

20. The structure of claim 18, wherein the first portion of the second semiconductor layer is physically separated from the second portion of the second semiconductor layer.
